(19) United States
(12) Patent Application Publication
(10) Pub. No.: US 2010/0247813 A1
(43) Pub. Date: Sep. 30, 2010

(54) Injection molded product and manufacturing method thereof

(75) Inventors: Young Min Kim, Seongnam-si (KR); Dong Yul Lee, Suwon-si (KR); Ah Hyun Bae, hwasseong-si (KR); Jun Gyu Song, Suwon-si (KR); Geun Ho Lee, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/659,643

(22) Filed: Mar. 16, 2010

(30) Foreign Application Priority Data
Mar. 26, 2009 (KR) 10-2009-0025962

(51) Int. Cl. G03F 1/14; B29C 45/14

(52) U.S. Cl. 428/14; 264/250; 264/254

(57) ABSTRACT

Disclosed herein are an injection molded product and a manufacturing method thereof. In the injection molded product, an insert defining a predetermined pattern may be injection molded to be enclosed by a transparent preform, thus appearing to float slightly above the bottom of the preform.

### CROSS-REFERENCE TO RELATED APPLICATION

This application claims priority under 35 U.S.C. §119 to Korean Patent Application No. 2009-0025962, filed on Mar. 26, 2009 in the Korean Intellectual Property Office (KIPO), the entire contents of which are incorporated herein by reference.

### BACKGROUND

1. Field

Example embodiments relate to an injection molded product in which an insert is provided in a preform, and a manufacturing method thereof.

2. Description of the Related Art

In a known laser processing technology, a laser is irradiated to a preform formed of glass or transparent plastic, to create, e.g., a desired pattern or letter that appears to float in the preform. Here, the term “appear to float” means that the patterns or letter created in the preform is sensed as floating slightly above the bottom of the preform.

However, it may be impossible, using the laser processing technology, to express certain features, e.g., colors and volumes of the patterns or letter.

Another known technology besides the laser processing technology is a glass art technology, in which glass of various colors is thermally processed into a glass product having patterns that appear to float. However, since the glass art technology entirely depends on a manual operation and thus, consumes an enormous operation time and a great number of operations, it may be unsuitable for mass production and it may be difficult to form a delicate pattern in glass. Moreover, always forming constant patterns, i.e. producing products of a constant quality, may be practically impossible.

### SUMMARY

Example embodiments provide an injection molded product which may be suited to mass production and may include a delicate pattern that appears to float, and a manufacturing method of the injection molded product.

Example embodiments will be set forth in part in the description which follows and, in part, will be obvious from the description, or may be learned by practice of example embodiments.

In accordance with example embodiment, an injection molded product may include at least one insert defining a pattern, and a preform enclosing the at least one insert so as to cause the at least one insert to appear to float.

In accordance with example embodiments, a method of manufacturing an injection molded product may include preparing a first preform by injection molding, providing the first preform with at least one insert that defines a pattern; and injection molding a second preform to enclose the at least one insert when coupled with the first preform to cause the at least one insert to appear to float.

Example embodiments provide a method of manufacturing an injection molded product by use of an injection molding apparatus comprising a movable mold, a first stationary mold configured to couple with the movable mold so as to define a molding space for molding a first preform, a second stationary mold configured to couple with the movable mold so as to define a molding space for molding an insert, and a third stationary mold configured to couple with the movable mold so as to define a molding space for molding a second preform. In example embodiments the method may include coupling the movable mold with the first stationary mold at a primary injection molding position to form the first preform, coupling the movable mold with the second stationary mold to form the insert, replacing the first stationary mold provided at the primary injection molding position with the third stationary mold, and coupling the movable mold with the third stationary mold to form the second preform. In example embodiments the first preform and the second preform may be molded to enclose the insert to cause the insert to appear to float.

In accordance with example embodiments, a method of manufacturing an injection molded product may include preparing an insert defining a pattern, injection molding a first preform of a resin on one side of the insert, and injection molding a second preform of a resin on another side of the insert. In example embodiments, the first preform and the second preform may enclose the insert so as to cause the insert to appear to float.

In accordance with example embodiments, an injection molded product may include at least one insert defining a predetermined pattern, and a transparent preform formed by injection molding to enclose the insert, so as to cause the insert to appear to float.

The insert may be formed of at least one of plastic, glass, ceramic, and metal.

The insert may be formed of colored resin.

The insert may be formed of a transparent material having a refractive index different from that of the preform.

The preform may include a first preform, and a second preform to enclose the insert together with the first preform.

The injection molded product may be one of a television case, an air conditioner case, and a cellular phone case.

In accordance with example embodiments, a method of manufacturing an injection molded product may include preparing a first preform of transparent resin by injection molding, providing the first preform with at least one insert that defines a predetermined pattern, and injection molding a transparent second preform to enclose the insert when coupled with the first preform, to cause the insert to appear to float.

The insert may be injection molded on the first preform.

The insert may be first manufactured and then, be disposed on the first preform.

In accordance with example embodiments, a method of manufacturing an injection molded product by use of an injection molding apparatus may include a movable mold, a first stationary mold to be coupled with the movable mold so as to define a molding space for molding of a first preform, a second stationary mold to be coupled with the movable mold so as to define a molding space for molding of an insert, and a third stationary mold to be coupled with the movable mold so as to define a molding space for molding of a second preform. In accordance with example embodiments, the method may include coupling the movable mold with the first stationary mold at a primary injection molding position, to form the first preform of a transparent material. The method may also include coupling the movable mold with the second stationary mold after moving the movable mold from the primary injection molding position to a secondary injection molding position, to form the insert. The method may also include replacing the first stationary mold provided at the primary injection molding position by the third stationary mold, and coupling the movable mold with the third stationary mold after moving the movable mold from the secondary injection molding position to the primary injection molding position, to form the second preform of a transparent material. In example embodiments, the first preform and second preform may be molded to enclose the insert, so as to cause the insert to appear to float.

In accordance with example embodiments, a method of manufacturing an injection molded product may include preparing an insert defining a predetermined pattern, injection molding a first preform of transparent resin on one side of the insert, and injection molding a second preform of transparent resin on the other side of the insert, and the first preform and second preform may be provided to enclose the insert, so as to cause the insert to appear to float.

### BRIEF DESCRIPTION OF THE DRAWINGS

Example embodiments will be more clearly understood from the following detailed description taken in conjunction with the accompanying drawings. FIGS. 1A-6D represent non-limiting, example embodiments as described herein. In the figures:

FIGS. 1A to 1E are process views illustrating a manufacturing method of an injection molded product according to example embodiments;

FIG. 2 is a perspective view illustrating an injection molded product manufactured by the method of FIGS. 1A to 1E;

FIGS. 3A and 3B are respectively a perspective view and a sectional view illustrating a cellular phone case having a pattern that appears to float according to example embodiments;

FIGS. 4A to 4D are process views illustrating a manufacturing method of an injection molded product according to example embodiments;

FIGS. 5A to 5E are process views illustrating a manufacturing method of an injection molded product according to example embodiments; and

FIGS. 6A to 6D are process views illustrating a manufacturing method of an injection molded product according to example embodiments.

### DETAILED DESCRIPTION

Example embodiments will now be described more fully with reference to the accompanying drawings, in which example embodiments are shown. The invention may, however, be embodied in different forms and should not be construed as limited to example embodiments set forth herein. Rather, example embodiments are provided so that this disclosure will be thorough and complete, and will fully convey the scope of the invention to those skilled in the art. In the drawings, the sizes of components may be exaggerated for clarity.

It will be understood that when an element or layer is referred to as being “on”, “connected to”, or “coupled to” another element or layer, it can be directly on, connected to, or coupled to the other element or layer or intervening elements or layers that may be present. In contrast, when an element is referred to as being “directly on”, “directly connected to”, or “directly coupled to” another element or layer, there are no intervening elements or layers present. As used herein, the term “and/or” includes any and all combinations of one or more of the associated listed items.

It will be understood that, although the terms first, second, etc. may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section. Thus, a first element, component, region, layer, or section discussed below could be termed a second element, component, region, layer, or section without departing from the teachings of example embodiments.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Example embodiments described herein will refer to plan views and/or cross-sectional views by way of ideal schematic views. Accordingly, the views may be modified depending on manufacturing technologies and/or tolerances. Therefore, example embodiments are not limited to those shown in the views, but include modifications in configuration formed on the basis of manufacturing processes. Therefore, regions exemplified in figures have schematic properties and shapes of regions shown in figures exemplify specific shapes or regions of elements, and do not limit example embodiments.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Reference will now be made in detail to example embodiments as illustrated in the accompanying drawings, wherein like reference numerals refer to like elements throughout.

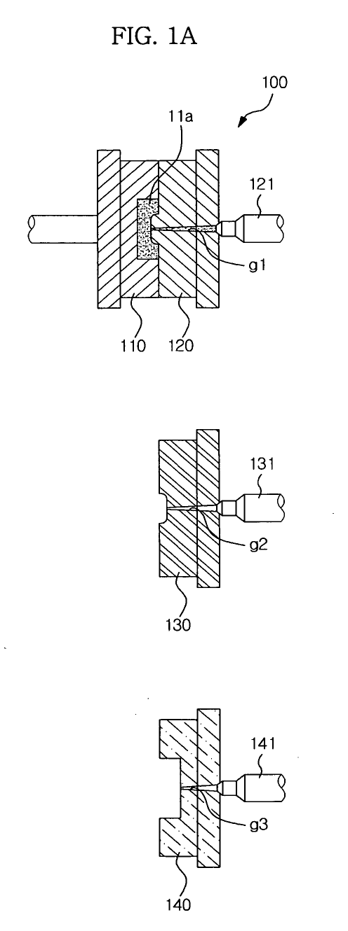

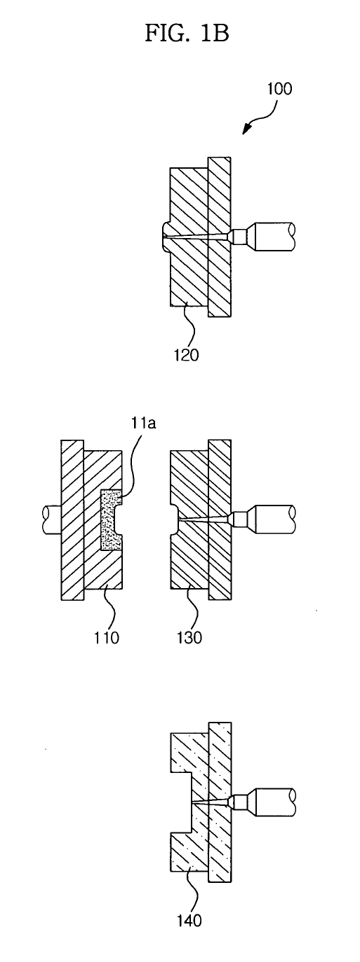

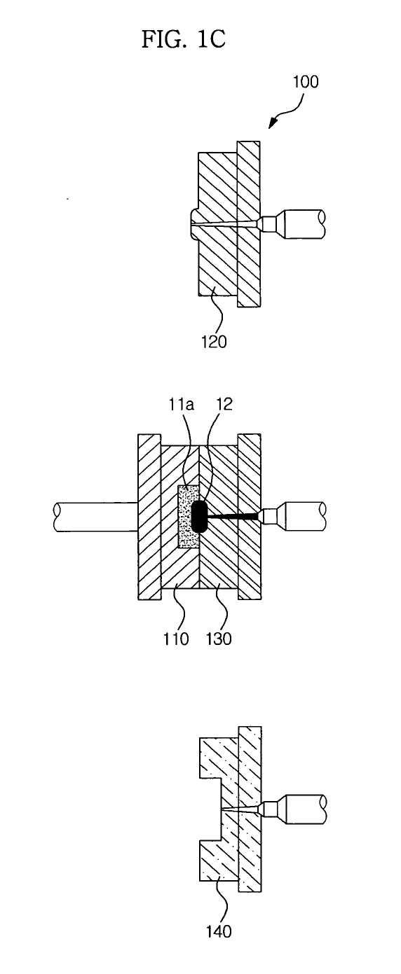

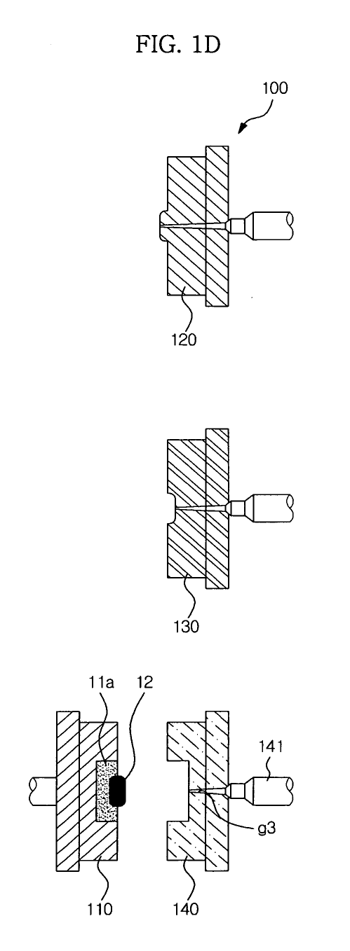

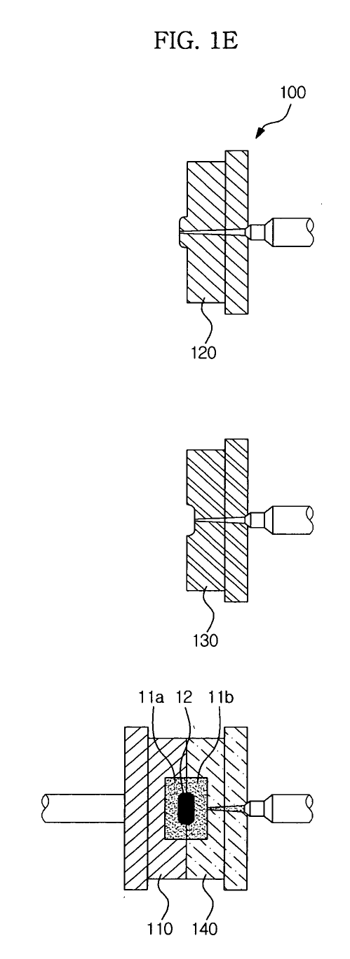

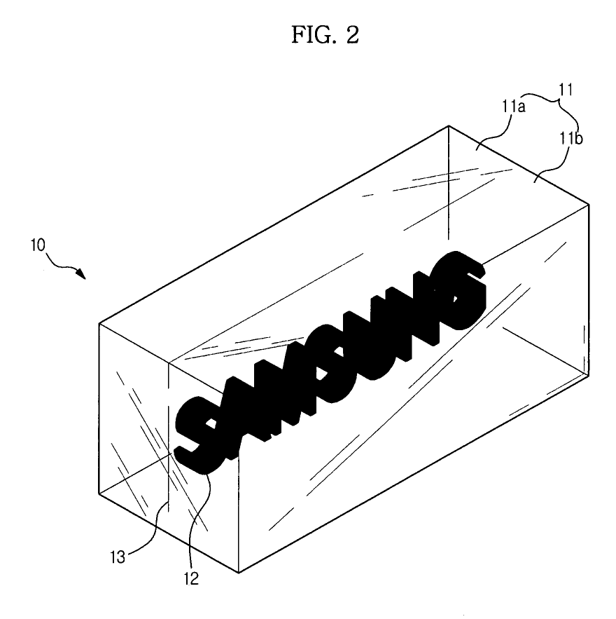

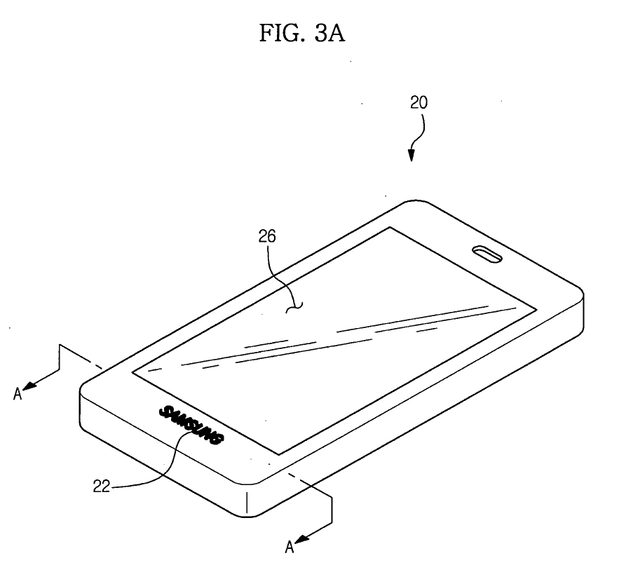

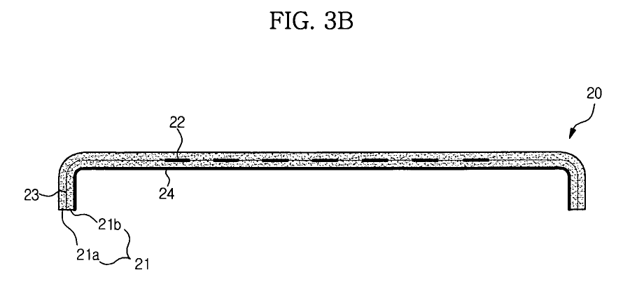

FIGS. 1A to 1E are process views illustrating a manufacturing method of an injection molded product according to example embodiments. FIG. 2 is a perspective view illustrating an injection molded product according to example embodiments. FIG. 3A is a perspective view illustrating a cellular phone case according to example embodiments. FIG. 3B is a sectional view taken along the line A-A of FIG. 3A.

As shown in FIGS. 1A to 1E, an injection molding apparatus 100 may include a movable mold 110, a first stationary mold 120, a second stationary mold 130, and a third stationary mold 140. Reference letters g1, g2 and g3 respectively represent gates provided in the respective stationary molds. Molten resin may be injected into a molding space through the gates g1, g2 and g3. Also, reference numerals 121, 131 and 141 respectively represent injection cylinders that supply molten resin into the respective molds.

The movable mold 110 may be coupled with the first stationary mold 120 to define a molding space for molding of a first preform 11a. As the molding space is filled with transparent resin, the first preform 11a is molded (see FIG. 1A).

The movable mold 110 may be moved to the second stationary mold 130 (see FIG. 1B) and may be coupled with the second stationary mold 130 to define a molding space for molding of an insert 12. As the molding space is filled with resin, the insert 12 is molded on the first preform 11a (see FIG. 1C). In example embodiments the resin may be a colored resin.

The movable mold 110, in which the first preform 11a and insert 12 are formed, may be moved to the third stationary mold 140 (see FIG. 1D) and may be coupled with the third stationary mold 140 to define a molding space for molding of a second preform 11b. As the molding space is filled with transparent resin, the second preform 11b is molded (see FIG. 1E). In example embodiments, the second preform 11b may be molded to enclose the insert 12 together with the first preform 11a.

As shown in FIG. 2, an injection molded product 10 manufactured by the above-described processes may include the insert 12 defining a pattern, and a transparent preform 11 injection molded to enclose the insert 12 so as to cause the insert 12 to appear to float. In example embodiments, the pattern may be a two-dimensional or three-dimensional letter, number, picture, or figure. In example embodiments, the pattern may be a predetermined or preset pattern.

As described above, the preform 11 of example embodiments may include the first preform 11a and the second preform 11b respectively made of transparent resin. For reference, reference numeral 13 of FIG. 2 is given for easy understanding of a boundary between the first preform 11a and the second preform 11b, and the boundary 13 is almost indistinguishable with the naked eye in an actual injection molded product. In example embodiments, to make it more difficult to distinguish the boundary 13, the first preform 11a and the second preform 11b may be made of the same kind of resin.

Accordingly, in the injection molded product of example embodiments, the insert 12 may appear to float slightly above the bottom of the preform 11 (see FIG. 2). In example embodiments, because a colored resin may be used to form the insert 12, the insert 12 may be a colored insert.

With the manufacturing method according to example embodiments, the injection molded product may be manufactured by systematized injection molding processes, representing a reduction in operation time and the number of operations as compared to conventional laser processing methods. In other words, the manufacturing method according to example embodiments may achieve an enhancement in productivity.

Further, with the manufacturing method according to example embodiments, the insert 12 defining a pattern may have a very delicate and constant shape. Thus, manufacture of an injection molded product having a relatively constant quality may be possible. In example embodiments, the pattern may be a predetermined or preset pattern.

FIGS. 3A and 3B illustrate an example of a cellular phone case manufactured by the manufacturing method according to example embodiments.

As shown, the cellular phone case 20 may include an insert 22 formed of a colored material to define a predetermined or preset letter, a transparent preform 21 injection molded to enclose the insert 22, and a print part 24 provided at a rear surface of the preform 21 to provide a display part 26.

The preform 21 according to example embodiments may include a first preform 21a and a second preform 21b, which may be respectively formed of transparent materials and may be coupled to each other to make it substantially impossible to distinguish a boundary 23 therebetween. The colored insert 22 may allow a user to sense that the insert 22 floats slightly above the print part 24 and this may further enhance an aesthetic value and quality grade of products. In example embodiments, the print part 24 may be a white print part.

The injection molded product manufactured by the method of example embodiments as shown in FIGS. 2, 3A and 3B is given by way of example, and the manufacturing method of example embodiments may be utilized in the manufacture of various products including, e.g., small decorative articles, advertising members as well as outer cases of a variety of electronic appliances, for example televisions, refrigerators, air conditioners, microwave ovens, and cellular phones. Although example embodiments may be utilized to manufacture the various products listed above, the list is not intended to limit example embodiments.

In addition, although the above description illustrates the insert as being injection molded on the first preform using resin, for example, a colored resin, the insert may be first formed using plastic, glass, ceramic, metal, or other materials and then, be disposed on the first preform.

In example embodiments, the insert may be molded using transparent resin having a refractive index different from that of the preform. In example embodiments, both the insert and the preform may be made of transparent materials. Therefore, although the shape of the insert provided in the preform may be indistinguishable under low light, the shape of the insert may appear due to a difference in the refractive indices when light is irradiated to the preform. This may enable expression of a higher quality of product.

The above-described manufacturing method of the injection molded product may be altered in various manners. Hereinafter, example embodiments describing various manufacturing methods are provided. For reference, the same and like constituent elements as the previously described constituent elements are designated by the same reference numerals and a description thereof will be omitted.

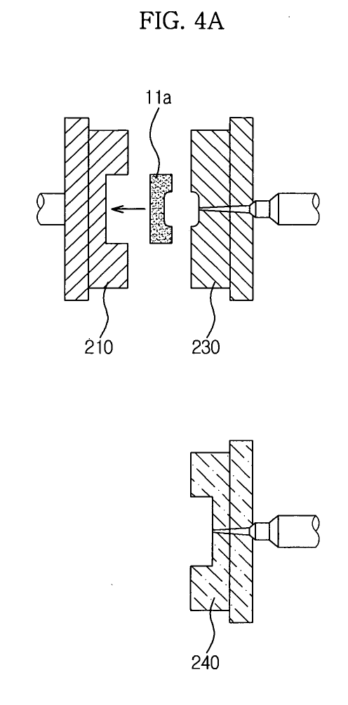

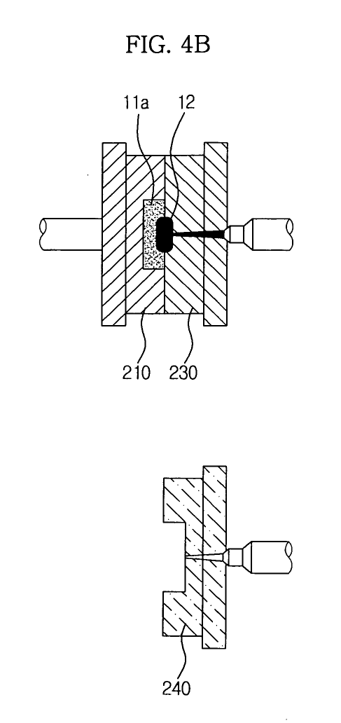

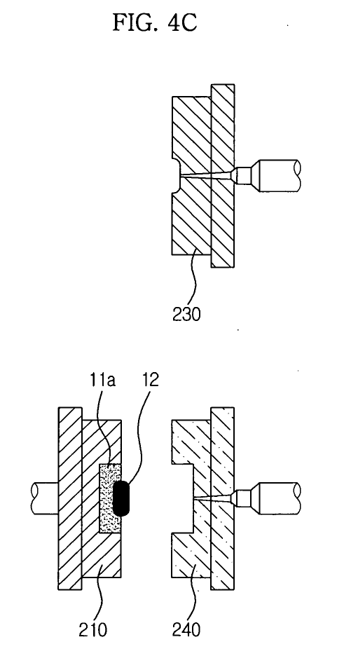

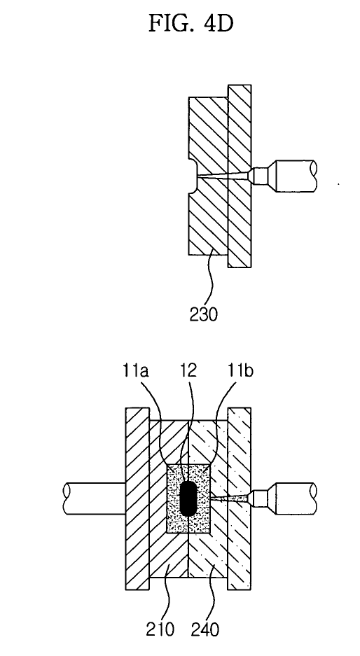

FIGS. 4A to 4D are process views illustrating a manufacturing method of an injection molded product according to example embodiments.

As shown, in the manufacturing method according to example embodiments, the first preform 11a may be formed by injection molding. The first preform 11a formed by injection molding may be inserted into a movable mold 210 (see FIG. 4A). The movable mold 210, in which the first preform 11a is inserted, may be coupled with a second stationary mold 230 to define a molding space for molding of the insert 12. As the molding space is filled with resin, the insert 12 is molded (see FIG. 4B). The movable mold 210 may be moved to a third stationary mold 240 (see FIG. 4C) and the movable mold 210 may be coupled with the third stationary mold 240 to define a molding space for molding of the second preform 11b. As the molding space is filled with resin, the second preform 11B is molded (see FIG. 4D).

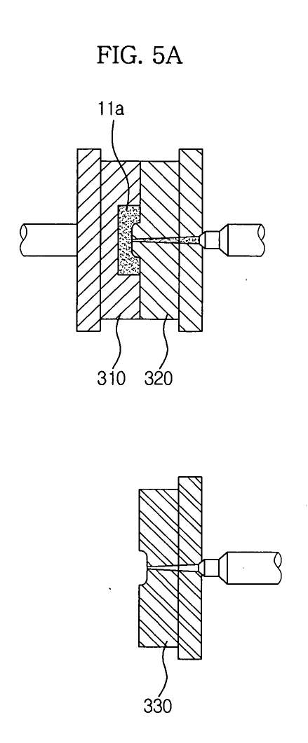

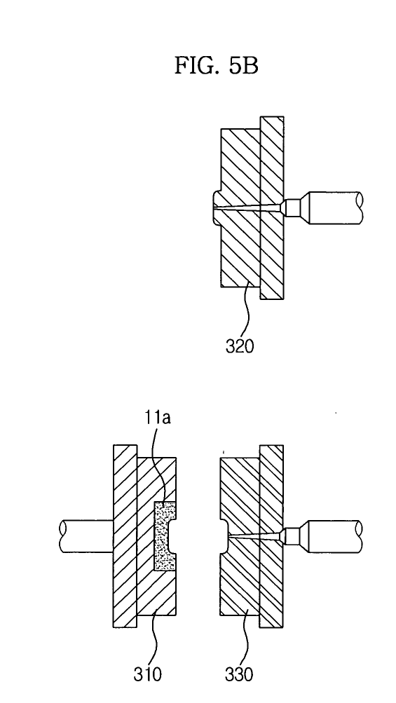

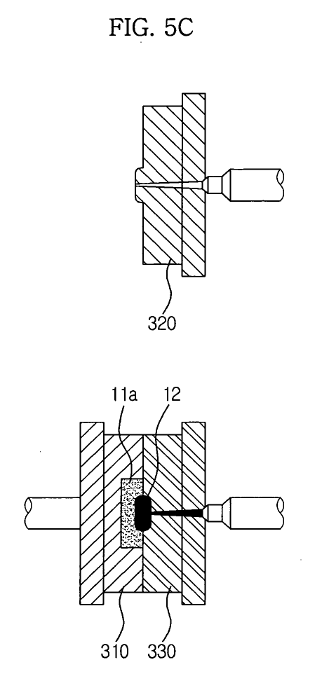

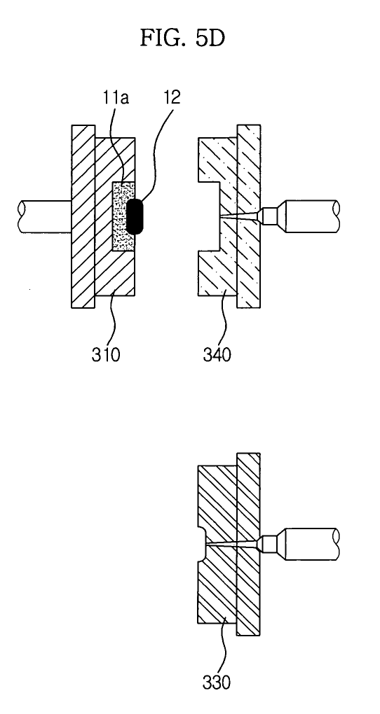

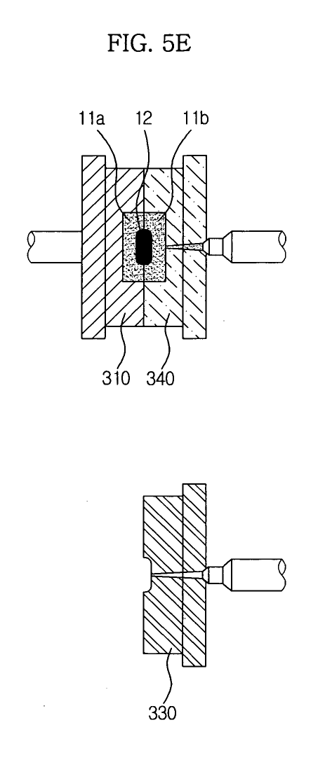

FIGS. 5A to 5E are process views illustrating a manufacturing method of an injection molded product according to example embodiments.

In the manufacturing method of example embodiments, a movable mold 310 may be coupled with a first stationary mold 320 at a primary injection molding position (the upper side of FIGS. 5A to 5E), to mold the first preform 11a (see FIG. 5A). In example embodiments, the movable mold 310 may be moved from the primary injection molding position to a secondary injection molding position (the lower side of FIGS. 5A to 5E) (see FIG. 5B) and the movable mold 310 may be coupled with a second stationary mold 330, to mold the insert 12 (see FIG. 5C). The first stationary mold 320 provided at the primary injection molding position may be replaced by a third stationary mold 340 (see FIG. 5D). The movable mold 310 may be moved from the secondary injection molding position to the primary injection molding position (see FIG. 5D) and the movable mold 310 may be coupled with the third stationary mold 340 to mold the second preform 11b (see FIG. 5E).

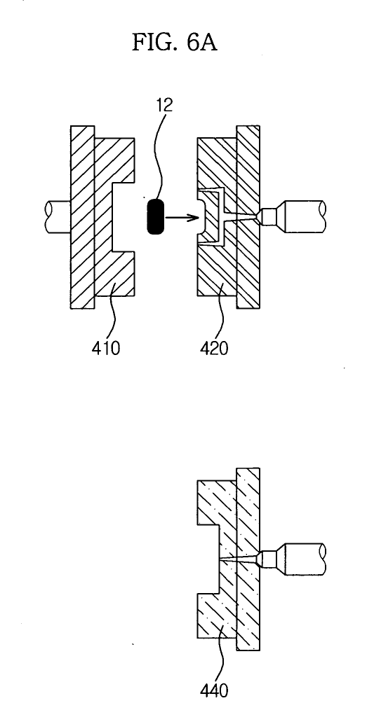

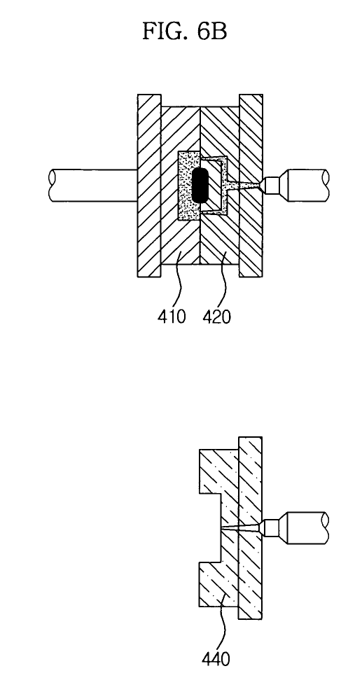

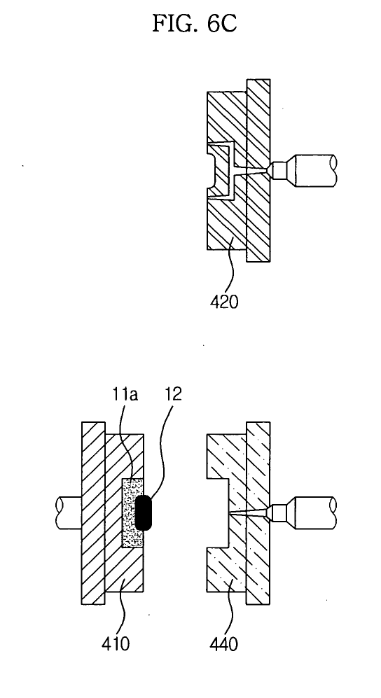

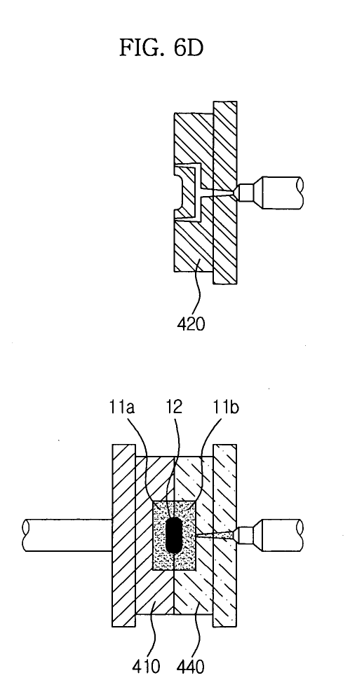

FIGS. 6A to 6D are process views illustrating a manufacturing method of an injection molded product according to example embodiments.

In the manufacturing method of example embodiments, the insert 12 defining a pattern may be prepared. In example embodiments, the insert 12 may be a predetermined or preset pattern. In example embodiments, the first preform 11a of transparent resin may be injection molded on one side of the insert 12 and the second preform 11b of transparent resin may be injection molded on the other side of the insert 12. In example embodiments, the first preform 11a and the second preform 11b may be configured to enclose the insert 12 so as to cause the insert 12 to appear to float. In other words, in the manufacturing method according to example embodiments, the insert 12 may be prepared and the first preform 11a and the second preform 11b may be formed by injection molding on opposite sides of the insert 12 using transparent resin.

Of course, various other modifications of example embodiments may be possible.

For example, although the preform described herein consists of two molded parts, the preform may be divided into three or more molded parts based on the configuration of a desired injection molded product.

Further, there is no limit in the color, shape and material of the insert. Of course, when the insert is manufactured by injection molding, the number of injection molding processes may increase based on the shape of the insert.

Furthermore, although the stationary molds described herein are arranged parallel to the movable mold, this arrangement is given by way of example and there is no limit in the arrangement of the stationary molds. For example, one or more pairs of two stationary molds may be arranged in a rotatable manner.

As is apparent from the above description, an injection molded product and a manufacturing method thereof according to example embodiments may achieve a remarkable reduction in operation time and the number of operation processes, resulting in enhanced productivity.

Further, the injection molded product and the manufacturing method thereof according to example embodiments may realize a delicate pattern that appears to float.

Although example embodiments have been shown and described, it would be appreciated by those skilled in the art that changes may be made in example embodiments without departing from the principles and spirit of the invention, the scope of which is defined in the claims and their equivalents.

What is claimed is:

1. An injection molded product comprising:
at least one insert defining a pattern; and
a preform enclosing the at least one insert so as to cause the at least one insert to appear to float.

2. The injection molded product according to claim 1, wherein the at least one insert includes at least one of plastic, glass, ceramic, and metal.

3. The injection molded product according to claim 1, wherein the at least one insert includes colored resin.

4. The injection molded product according to claim 1, wherein the at least one insert includes a transparent material having a refractive index different from that of the preform.

5. The injection molded product according to claim 1, wherein the preform includes a first preform and a second preform, the first preform and the second preform enclosing the at least one insert.

6. The injection molded product according to claim 1, wherein the injection molded product is one of a television case, an air conditioner case, and a cellular phone case.

7. The injection molded product according to claim 1, wherein the preform is transparent.

8. A method of manufacturing an injection molded product comprising:
preparing a first preform by injection molding;
providing the first preform with at least one insert that defines a pattern; and
injection molding a second preform to enclose the at least one insert when coupled with the first preform, to cause the at least one insert to appear to float.

9. The method according to claim 8, wherein the at least one insert is injection molded on the first preform.

10. The method according to claim 8, wherein the at least one insert is first manufactured and then provided to the first preform.

11. The method according to claim 8, wherein the first and second preforms are formed as transparent materials.

12. A method of manufacturing an injection molded product by use of an injection molding apparatus comprising a movable mold, a first stationary mold configured to couple with the movable mold so as to define a molding space for molding a first preform, a second stationary mold configured to couple with the movable mold so as to define a molding space for molding an insert, and a third stationary mold configured to couple with the movable mold so as to define a molding space for molding a second preform, the method comprising:
coupling the movable mold with the first stationary mold at a primary injection molding position to form the first preform;
coupling the movable mold with the second stationary mold to form the insert;
replacing the first stationary mold provided at the primary injection molding position with the third stationary mold; and
coupling the movable mold with the third stationary mold to form the second preform,
wherein the first preform and the second preform are molded to enclose the insert to cause the insert to appear to float.

13. The method according to claim 12, wherein
coupling the movable mold with the second stationary mold occurs after moving the movable mold from the primary injection molding position to a secondary injection molding position, and
coupling the movable mold with the third stationary mold occurs after moving the movable mold from the secondary injection molding position to the primary injection molding position.

14. The method according to claim 12, wherein the first and second preforms are formed to be transparent.

15. The method according to claim 12, wherein an index of refraction of the insert is different from an index of refraction of the first and second preforms.

16. A method of manufacturing an injection molded product comprising:
preparing an insert defining a pattern;
injection molding a first preform of a resin on one side of the insert; and
injection molding a second preform of a resin on another side of the insert,
wherein the first preform and second the preform enclose the insert so as to cause the insert to appear to float.

17. The method according to claim 16, wherein the insert is prepared according to a predefined pattern.

18. The method according to claim 16, wherein the first and second preforms are formed to be transparent.

19. The method according to claim 16, wherein an index of refraction of the insert is different from an index of refraction of the first and second preforms.

20. The method according to claim 16, wherein the insert is colored.
